(19) United States
(12) Patent Application Publication
(10) Pub. No.: US 2003/0183916 A1
(43) Pub. Date: Oct. 2, 2003

(54) Packaging microelectromechanical systems

(76) Inventors: John Heck, Mountain View, CA (US); Michele J. Berry, Chandler, AZ (US); Daniel Wong, Fremont, CA (US); Valluri Rao, Saratoga, CA (US)

Correspondence Address: Timothy N. Trop, TROP, PRUNER & HU, P.C., STE 100, 8554 KATY FWY, HOUSTON, TX, 77024-1841, US

(21) Appl. No.: 10/107,624

(22) Filed: Mar. 27, 2002

(51) Int. Cl. H01L 23/06

(52) U.S. Cl. 257/684

(57) ABSTRACT

A packaged microelectromechanical system may be formed in a hermetic cavity by forming the system on a semiconductor structure and covering the system with a thermally decomposing film. That film may then be covered by a sealing cover. Subsequently, the thermally decomposing material may be decomposed, forming a cavity, which can then be sealed to hermetically enclose the system.

### BACKGROUND

This invention relates generally to microelectromechanical systems (MEMS) and particularly to packaging for such systems.

A MEMS device is generally a delicate mechanical structure formed by an etching technique that allows the device to move freely. As a result, there is a need to encapsulate MEMS devices for controlling the pressure and composition of the environment in which those devices operate. The devices also need to be protected from destructive processes involved in standard packaging including dicing and cleaning. In addition, there is a need to reduce the cost of packaging MEMS devices by reducing the amount of die space used by the packaging. Generally the more die space that is utilized the more expensive the resulting MEMS.

Thus, there is a need for better ways to package MEMS devices.

### BRIEF DESCRIPTION OF THE DRAWINGS

FIG. 1 is an enlarged cross-sectional view of a packaged MEMS device in accordance with one embodiment of the present invention;

FIG. 2 is an enlarged cross-sectional view at an early stage of manufacturing of the device shown in FIG. 1 in accordance with one embodiment of the present invention;

FIG. 3 is an enlarged cross-sectional view of a subsequent stage of manufacturing in accordance with one embodiment of the present invention.

FIG. 4 is an enlarged cross-sectional view at a subsequent stage of manufacturing in accordance with one of the present invention;

FIG. 5 is an enlarged cross-sectional view at a subsequent stage of manufacturing in accordance with one embodiment of the present invention;

FIG. 6 is an enlarged cross-sectional view at a subsequent stage of manufacturing in accordance with one embodiment of the present invention;

FIG. 7 is an enlarged cross-sectional view at a subsequent stage of manufacturing in accordance with one embodiment of the present invention;

FIG. 8 is an enlarged cross-sectional view at a subsequent stage of manufacturing in accordance with one embodiment of the present invention; and

FIG. 9 is an enlarged cross-sectional view of another embodiment of the present invention.

### DETAILED DESCRIPTION

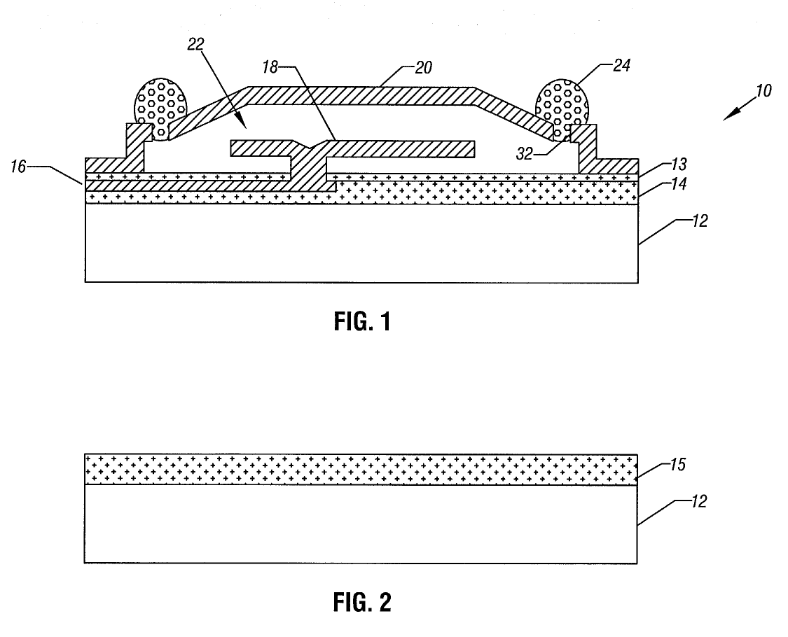

Referring to FIG. 1, a package 10 may include a microelectromechanical system (MEMS) device 18 within a cavity 22 defined between a cover 20 and a semiconductor structure 12. Openings 32 in the cover 20 may be plugged with the patch 24 in one embodiment of the present invention.

Electrical connections from the outside world may be made to the MEMS device 18 through an interconnection layer 16 which is buried within the semiconductor structure 12. In particular, the interconnection layer 16 may be above a layer 14 and below a layer 13 that may be formed of any dielectric material. In one embodiment, the layer 13 is an oxide. As a result, electrical connections can be made to the MEMS device 18, bypassing the cover 20 and avoiding the need to penetrate the cover 20. Penetrating the cover 20 may compromise the environment within the cavity 22, and if the cover 20 is electrically conductive, the electrical connections 16 would be electrically shorted. In some embodiments, the cavity 22 may be a vacuum cavity but in general, it may be desirable in many embodiments to maintain a hermetic seal in the cavity 22.

Referring to FIG. 2, the fabrication of the package 10 shown in FIG. 1 begins by depositing a sacrificial layer 15 on the semiconductor structure 12. The sacrificial layer 15 may include a thermally decomposing film that may be formed for example by a spin-on process. The film may be one that decomposes to form a gas at temperatures above 350° C. in one embodiment. In one embodiment the film may be polynorbornene that decomposes at a temperature of 425° C. The preparation of polynorbornene is described in Bhusari et al., “Fabrication of Air-Channel Structures for Microfluidic, Microelectromechanical, and Microelectronic Applications,” Journal of Microelectromechanical Systems, Vol. 10, No. 3, September 2001 at page 400. Polynorbornene functionalized with triethoxysilyl (TES) adheres to oxides so the layer 13 may be an oxide in one embodiment.

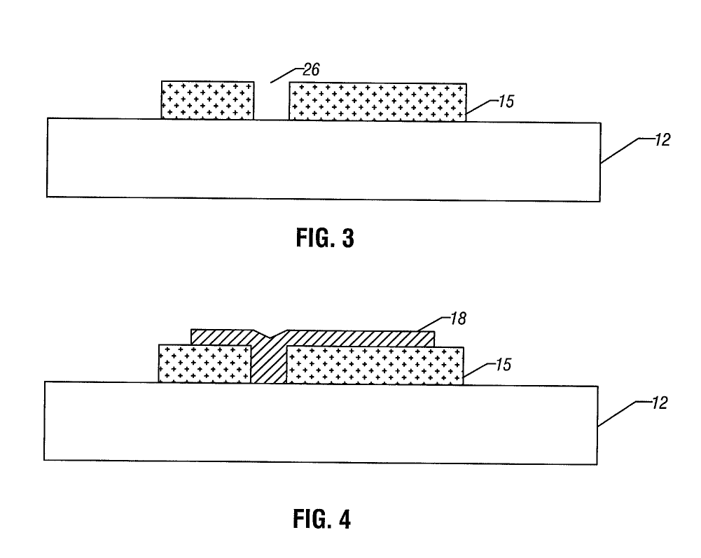

Referring to FIG. 3, the film 15 may be patterned using conventional techniques to form an aperture through the film 26. As shown in FIG. 4, the MEMS device 18 may be formed, for example, by depositing and patterning techniques.

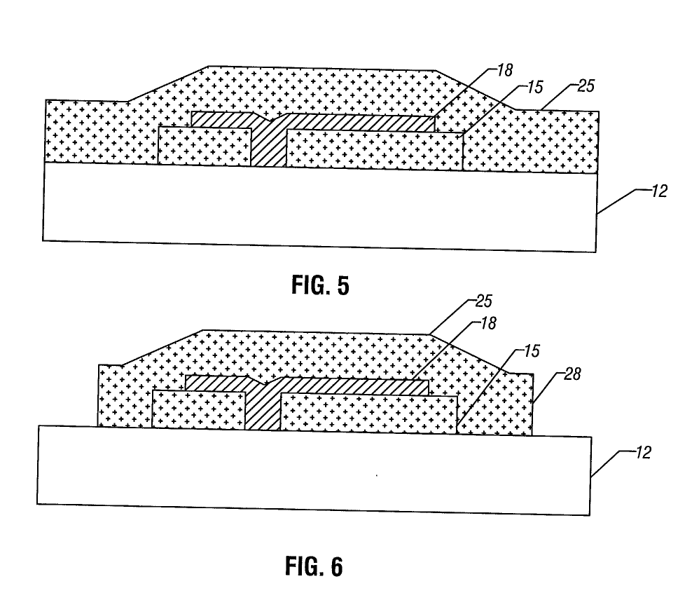

Referring to FIG. 5, a second layer 25 of the thermally decomposing film may then be formed as shown in FIG. 5. As a result of the imposition of the patterned layer 15 and the MEMS device 18, a humped configuration may result in some embodiments. As shown in FIG. 6, the layer 25 may be patterned to form edges 28.

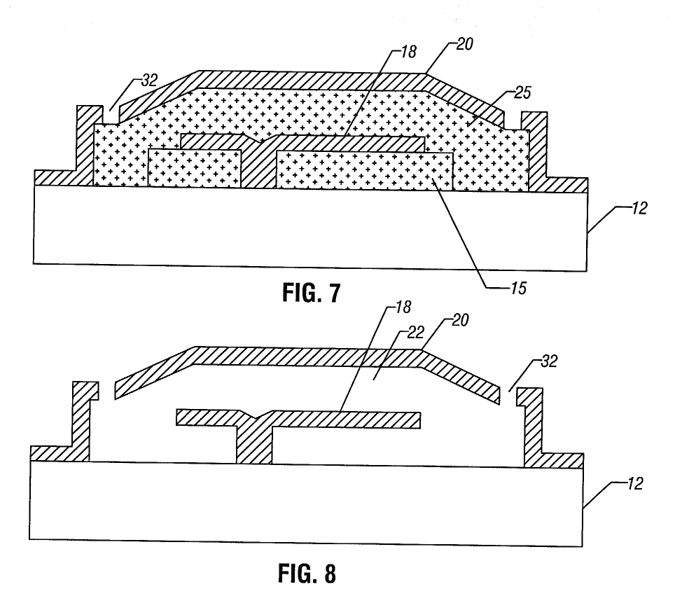

As shown in FIG. 7, a cover 20 may be formed, for example, by a deposition, encapsulating the MEMS device 18 and the layers 15 and 25. Openings 32 may be formed in the cover using patterning techniques in one embodiment of the present invention. The cover 20 may be formed of a variety of materials including a metal or a dielectric or a combination of metals and dielectrics that can form a hermetic barrier. The openings 32 may be patterned so that the sacrificial layers 25 and 15 may be removed by thermal decomposition.

Referring to FIG. 8, the structure shown in FIG. 7 may be exposed to elevated temperatures that cause the layers 15 and 25 to thermally decompose releasing the MEMS device 18 and creating a cavity 22 beneath the cover 20. In one embodiment the thermally decomposed material sublimates in response to heating and passes as a gas through the openings 32. Any technique for heating the layers 15 and 25 can be used including baking or exposure to infrared or other energy sources.

Referring to FIG. 1, a patch 24 may simply be deposited or printed directly onto the holes 32 to seal the cavity 22. In one embodiment the sealing process may be done in a controlled environment so that the cavity 22 contains the desired ambient gas at the desired pressure. The holes may be positioned far enough away from the device 18 that the device 18 is not affected by that deposition process. The patch 24 may be formed of epoxy, solder, or frit glass as three examples.

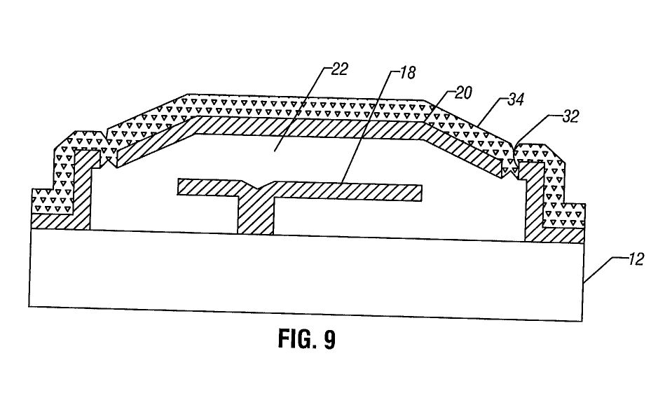

Referring next to FIG. 9, in accordance with another embodiment of the present invention a sealing material 34 may be formed over the entire cover 20, sealing the holes 32 at the same time. Sealing the entire cover 20 may improve the cover's ability to maintain the hermetic cavity 22. In one embodiment, the cover 20 may be formed without openings 32 by making the cover 20 sufficiently porous to pass the decomposed layers 15 and 25. In such an embodiment, the sealing material 34 thereafter provides the barrier needed to seal the cavity 22.

Some embodiments of the present invention may have various advantages. For example, some embodiments may be advantageous because the release process is done at the wafer level, eliminating the need for expensive die-level processing. Particularly, the embodiments shown in FIGS. 1-9 may be wafers that have not yet been severed into dice. As a result, all the processing shown in those figures, in some embodiments, may be done at the wafer level. This eliminates the need for expensive die-level processing in some embodiments.

In accordance with some embodiments of the present invention, a relatively smaller amount of area on a die is dedicated to encapsulating the MEMS devices 18. Again, reducing the amount of die area devoted to the encapsulation technique reduces the cost of the resulting packaged product.

In some embodiments, the release process uses a thermal decomposition film, eliminating any stiction problem. Stiction occurs in processes where a liquid etchant is used to release a MEMS structure. The liquid-vapor meniscus forces delicate mechanical elements into contact, where solid bridging, van der Waals forces and/or hydrogen bonding may result in permanent bonding of the structures.

In some embodiments, the packaging process may be performed using standard deposition and etch processes. Such processes may be readily integrated into existing process flows.

In addition, in some embodiments, once the device 18 is sealed, conventional integrated circuit packaging techniques may be utilized. Therefore, expensive specialty processes for MEMS packaging such as wafer bonding may not be necessary.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a microelectromechanical system on a semiconductor structure;
covering said system with a thermally decomposing layer;
forming a cover over said thermally decomposing layer; and
thermally decomposing the thermally decomposing layer underneath said cover.

2. The method of claim 1 wherein thermally decomposing includes causing the thermally decomposing layer to sublimate.

3. The method of claim 2 including forming openings in said cover to allow the release of said sublimated layer.

4. The method of claim 3 including closing said openings after said film has been thermally decomposed.

5. The method of claim 4 including coating said cover to close said openings.

6. The method of claim 4 including depositing a sealing material over said openings without covering the entire cover.

7. The method of claim 1 including allowing the thermally decomposing material to escape through said cover and thereafter sealing said cover.

8. The method of claim 1 including removing the thermally decomposing layer and forming a hermetic cavity between said cover and said structure around said microelectromechanical system.

9. The method of claim 1 including providing an electrical connection to said microelectromechanical system through said semiconductor structure.

10. The method of claim 1 including forming an electrical connection to said system without penetrating said cover.

11. A microelectromechanical structure comprising:
a semiconductor layer;
a microelectromechanical system formed on said layer;
a thermally decomposing layer formed over said system; and
a cover over said thermally decomposing layer.

12. The structure of claim 11 wherein said structure is a semiconductor wafer.

13. The structure of claim 11 wherein said thermally decomposing layer is formed of a material that decomposes at a temperature above 350° C.

14. The structure of claim 13 wherein said material includes polynorbornene.

15. The structure of claim 11 wherein said thermally decomposing layer is formed of a material that sublimates to form a gas when heated.

16. The structure of claim 11 wherein said cover is sufficiently non-porous to define a hermetic cavity.

17. The structure of claim 11 wherein said cover includes a plurality of apertures through said cover.

18. The structure of claim 11 including a buried interconnection layer extending through said semiconductor layer and electrically coupling said system.

19. The structure of claim 11 including a first sublayer of thermally decomposing material formed at least partially beneath said system and a second sublayer of thermally decomposing material formed over said system.

20. A packaged microelectromechanical structure comprising:
a semiconductor layer;
a microelectromechanical system formed on said layer;
a cover over said system defining a hermetic cavity between said cover and said layer and surrounding said system; and
a sealing material over said cover to maintain said hermetic cavity.

21. The structure of claim 20 wherein said structure is a semiconductor die.

22. The structure of claim 20 wherein said cover includes an aperture through said cover.

23. The structure of claim 22 including a sealing patch over said aperture.

24. The structure of claim 20 wherein said material extends over said entire cover.

25. The structure of claim 20 including a buried interconnection layer coupled to said system and extending outwardly of said cover.
